(19) United States
(12) Patent Application Publication
(10) Pub. No.: US 2023/0130385 A1
(43) Pub. Date: Apr. 27, 2023

(54) METHOD FOR FORMING A PATTERN

(71) Applicant: Tokyo Electron Limited, Tokyo (JP)

(72) Inventors: Takahiro YONEZAWA, Kurokawa-gun (JP); Koki TANAKA, Kurokawa-gun (JP)

(73) Assignee: Tokyo Electron Limited, Tokyo (JP)

(21) Appl. No.: 18/048,618

(22) Filed: Oct. 21, 2022

(30) Foreign Application Priority Data
Oct. 25, 2021 (JP) 2021-173638

(51) Int. Cl. G03F 7/004; G03F 7/20; G03F 7/36; G03F 7/16

(52) U.S. Cl. CPC G03F 7/0041; G03F 7/2002; G03F 7/36; G03F 7/168

(57) ABSTRACT

In one exemplary embodiment, a method for forming a pattern includes (a) forming, on a substrate, a first pattern having an opening and containing a first material, (b) forming a filling portion in the opening, the filling portion containing a second material different from the first material, and (c) removing the first pattern so that the filling portion remains as a second pattern inverted with respect to the first pattern. At least one of the first material or the second material contains tin.

### CROSS-REFERENCE To RELATED APPLICATIONS

This application is based on and claims the benefit of priority from Japanese Patent Application No. 2021-173638 filed on Oct. 25, 2021, the entire contents of which are incorporated herein by reference.

### FIELD

Exemplary embodiments of the present disclosure relate to a method for forming a pattern,

### BACKGROUND

Japanese Unexamined Patent Publication No. 2016-539361 discloses a method for patterning a substrate. In the method, first, a substrate including a radiation sensitive layer is received, Then, a patterned resist mask is produced on the substrate by developing a pattern transferred to the radiation sensitive layer through an extreme ultraviolet lithography process. Then, the patterned resist mask is overcoated with an image inversion material. Then, the upper portion of the image inversion material is removed. Then, a patterned image inversion material mask is produced by removing the patterned resist mask.

### SUMMARY

In one exemplary embodiment, a method for forming a pattern includes (a) thrilling, on a substrate, a first pattern having an Opening and containing a first material, (b) forming a filling portion in the opening, the filling portion containing a second material different from the first material, and (c) removing the first pattern so that the filling portion remains as a second pattern inverted with respect to the first pattern. At least one of the first material or the second material contains tin.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPT1ON OF THE DRAWINGS

FIG. 1 is a flow diagram illustrating a pattern forming method according to one exemplary embodiment.

FIGS. 2A to 2C are cross-sectional views illustrating sonic steps of a pattern forming method according to a first exemplary embodiment,

FIGS. 3A to 3C are cross-sectional views illustrating some steps of the pattern forming method according to the first exemplary embodiment.

FIGS. 4A to 4D are cross-sectional views illustrating some steps of a pattern forming method according to a second exemplary embodiment.

FIGS. 5A to 5C are cross-sectional views illustrating some steps of a pattern forming method according to a third exemplary embodiment.

FIGS. 6A to 6C are cross-sectional views illustrating some steps of the pattern forming method according to the third exemplary embodiment.

FIGS. 7A and 7B are cross-sectional views illustrating some steps of a pattern forming method according to a fourth exemplary embodiment.

FIGS. 8A to 8C are cross-sectional views illustrating some steps of the pattern forming method according to the fourth exemplary embodiment.

FIG. 9 is a flow diagram illustrating a pattern forming method according to one exemplary embodiment.

FIGS. 10A to 10C are cross-sectional views illustrating some steps of a pattern forming method according to a fifth exemplary embodiment.

FIG. 11 is a flow diagram illustrating a pattern forming method according to one exemplary embodiment.

FIGS. 12A to 12C are cross-sectional views illustrating some steps of a pattern forming method according to a sixth exemplary embodiment.

FIG. 13 is a diagram schematically illustrating an apparatus for performing a pattern forming method according to one exemplary embodiment.

FIG. 14 is a diagram schematically illustrating an apparatus for performing a pattern forming method according to another exemplary embodiment.

### DETAILED DESCRIPT1ON

Hereinafter, various exemplary embodiments will be described.

In one exemplary embodiment, a method for forming a pattern includes (a) forming, on a substrate, a first pattern having an opening and containing a first material, (b) forming a filling portion in the opening, the filling portion containing a second material different from the first material, and (c) removing the first pattern so that the filling portion remains as a second pattern inverted with respect to the first pattern. At least one of the first material or the second material contains tin.

According to the above method, it is possible to invert the pattern from the first pattern to the second pattern.

The first material may contain tin. In this case, the pattern can be inverted from the first pattern containing tin to the second pattern.

The first material may contain tin oxide.

The second material may contain at least one of carbon, silicon, or metal.

In (c), the first pattern may be removed by using a hydrogen bromide gas. In this case, since the first pattern can be removed without using plasma, it is possible to increase the etching selectivity of the first pattern to the filling portion.

The second material may contain tin. In this case, the pattern can be inverted from the first pattern to the second pattern containing tin.

The second material may contain tin oxide.

The first material may contain at least one of carbon, silicon, or metal.

The first material may contain tin. The second material may contain at least one of carbon, silicon, or metal. In (c), the first pattern may be removed by using at least one of a hydrogen fluoride gas, a hydrogen chloride gas, a hydrogen bromide gas, a hydrogen iodide gas, a fluorine gas, a chlorine gas, a bromine gas, an iodine gas, a boron trichloride gas, a helium gas, a neon gas, an argon gas, a xenon gas, a nitrogen gas, a hydrocarbon gas, or a methanol gas.

The first material may contain tin oxide, and the second material may contain at least one of carbon or silicon.

In (c), the first pattern may be removed. by using at least one of the hydrogen bromide gas or the hydrocarbon gas.

The first material may contain carbon. The second material may contain tin. In (c), the first pattern may be removed by using at least one of an oxygen-containing gas, a fluorine-containing gas, or a nitrogen-containing gas.

The first material may contain silicon, and the second material may contain tin. In (c), the first pattern may be removed by using a fluorine-containing gas.

The first material may contain tin. The second material may contain tin oxide. An oxygen concentration of the second material may be higher than an oxygen concentration of the first material. In (c), the first pattern may be removed by using at least one of a hydrogen fluoride gas, a hydrogen chloride gas, a hydrogen bromide gas, a hydrogen iodide gas, a fluorine gas, a chlorine gas, a bromine gas, an iodine gas, a boron trichloride gas, a helium gas, a neon gas, an argon gas, a xenon gas, a nitrogen gas, a hydrocarbon gas, or a methanol gas.

An either one pattern containing tin of the first pattern and the second pattern may be formed from a CND film or an ALD film.

The CND film or the ALL) film may be a tin-containing photoresist film.

The photoresist film may be a photoresist film for EUV exposure.

An unexposed portion of the photoresist film may contain tin. An exposed portion of the photoresist film may contain tin oxide. An oxygen concentration in the exposed portion may be higher than an oxygen concentration in the unexposed portion.

(a) may include (a1) forming a mask pattern corresponding to the first pattern, on an underlying film provided on the substrate, and (a2) forming the first pattern by etching the underlying film with the mask pattern. In this case, it is possible to form a pattern corresponding to the first pattern from the underlying film.

The underlying film may include at least one of a silicon-containing film or a carbon-containing film.

The filling portion may be a first filling portion, The method may further include (d) forming a second filling portion containing a third material different from the first material and the second material, in an opening of the second pattern, and (e) removing the second pattern so that the second filling portion remains as a third pattern corresponding to the first pattern. In this case, it is possible to obtain a third pattern that is made of a different material from the material of the first pattern and that has the same shape as the first pattern.

The filling portion may be a first filling portion. The method may further include, before (a), (f) forming, on the substrate, a third pattern having an opening and containing a third material, the third material being different from the first material and the second material, and (g) forming a second filling portion containing the first material in the opening of the third pattern. In (a), the third pattern may be removed so that the second filling portion may remain as the first pattern. In this case, it is possible to obtain the second pattern that is made of a different material from the material of the third pattern and that has the same shape as the third pattern.

In the following detailed description, reference is made to the accompanying drawings, which form a part hereof The exemplary embodiments described in the detailed description, drawing, and claims are not meant to be limiting. Other exemplary embodiments may be utilized, and other changes may be made, without departing from the spirit or scope of the subject matter presented here.

The present disclosure provides a pattern forming method capable of forming an inverted pattern.

Hereinafter, various exemplary embodiments will be described in detail with reference to the drawings. In the drawings, the same or corresponding portions are denoted by the same reference signs.

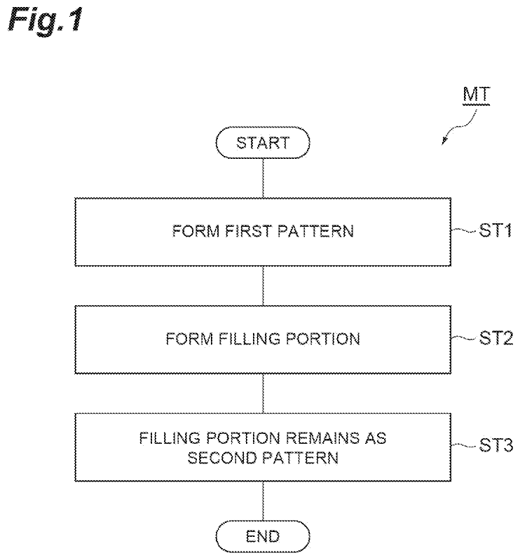

FIG. 1 is a flow diagram illustrating a pattern forming method according to one exemplary embodiment. The method illustrated in FIG. 1 (referred to as a “method MT” below) includes Steps ST1, ST2, and ST3. Steps ST1 to ST3 may be performed in this order. A method MT in a first embodiment to a method MT in a fourth embodiment will be described below.

### First Embodiment

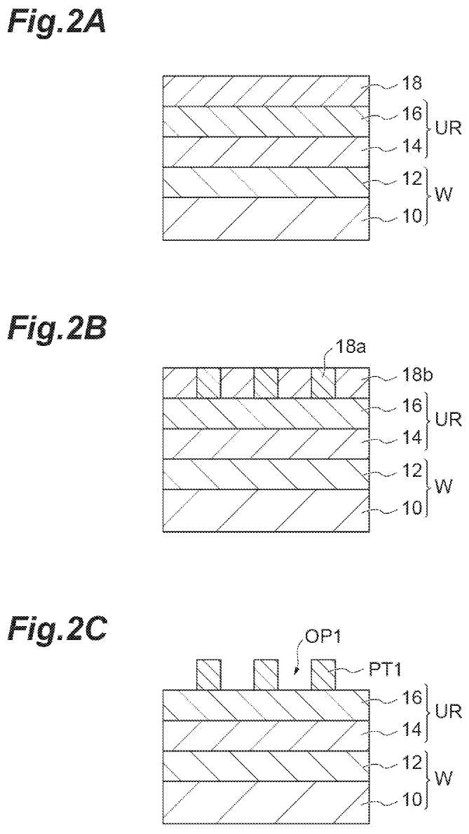

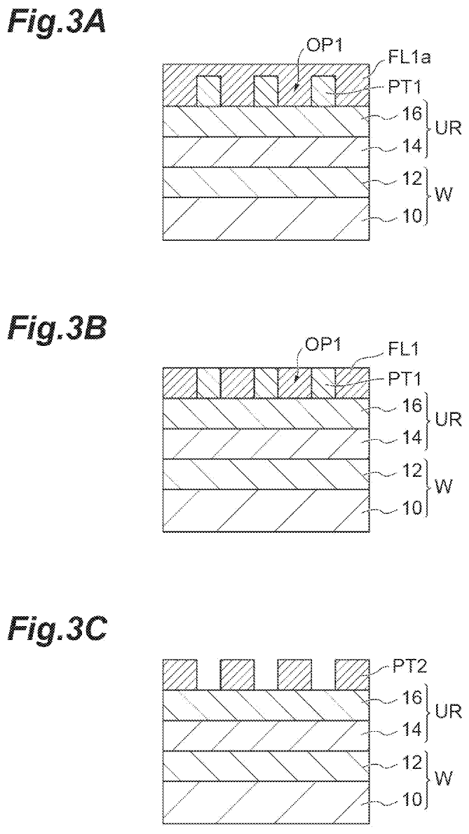

FIGS. 2A to 2C and FIGS. 3A to 3C are cross-sectional views illustrating some steps of the pattern forming method according to the first embodiment. The method MT in the first embodiment will be described below with reference to FIGS. 1 to 3C.

In Step ST1, a pattern PT1 (first pattern) having an opening OP1 is formed on a substrate W, as illustrated in FIGS. 2A to 2C. The pattern PT1 contains a first material, In the present embodiment, the first material contains tin (Sn). The first material may contain tin oxide (SnO). Examples of the first material include tin-containing resist materials. The opening OP1 is, for example, a hole. Step ST1 may be performed as follows.

First, a photoresist film 18 is formed on the substrate W as illustrated in FIG. 2A. The substrate W may include a silicon-containing film 10 and an oxide film 12. The oxide film 12 is disposed between the silicon-containing film 10 and the photoresist film 18. The oxide film 12 is, for example, a silicon oxide film. An underlying film UR may be provided on the substrate W. The underlying film UR may include a first layer 14 and a second layer 16. The first layer 14 is disposed between the oxide film 12 and the second layer 16. The first layer 14 may be, for example, a carbon-containing film such as a carbon film. The second layer 16 may be a silicon-containing film. Examples of the silicon-containing film include a silicon oxide (SiOₓ) film, a silicon nitride (SiN) film, a silicon carbide (SiC) film, and a silicon oxynitride (SiON) film.

The photoresist film 18 may be formed on the underlying film UR. The photoresist film 18 contains tin, The photoresist film 18 may be a negative resist film. The photoresist film 18 may be formed by a wet process or a dry process. Examples of the wet process include coating. The photoresist film 18 may be formed by coating the substrate W with a tin-containing resist material, for example. Examples of the dry process include CVD. The photoresist film 18 may be formed by CVD using a tin-containing gas, Examples of the tin-containing gas include an organotin compound gas, a SnCl₄ gas, a Sn(CH₃)₄ gas, and a SnH₄ gas.

Then, as illustrated in FIG. 2B, the photoresist film 18 is exposed by using, for example, a photomask. An exposed portion 18a and an unexposed portion 18b are formed from the photoresist film 18 by the exposure. Tin oxide may be produced in the exposed portions 18a by the exposure. Extreme ultraviolet (EUV) or other kinds of light may be used in the exposure.

Then, as illustrated in FIG. 2C, the unexposed portion 18b) is removed by development to form an opening OP1. As a result, the exposed portion 18a remains as the pattern PT1, The unexposed portions 18b may be removed by a wet process or a dry process. In the dry process, the temperature may be equal to or higher than −60° C. and equal to or lower than 120° C. The pressure may be equal to or greater than 0.1 mTorr (0.01333 Pa) and equal to or smaller than 760 mTorr (101.308 kPa). The unexposed portion 18b may be removed by a substance containing at least one of hydrogen or halogen. Examples of the halogen-containing substance include a fluorine gas (F₂), a chlorine gas (Cl₂), a bromine gas (Br₂), an iodine gas (I₂), and a boron trichloride gas (BCl₃). The unexposed portion 18b may be removed by a substance containing at least one of hydrogen, chlorine, or bromine, for example. The substance containing hydrogen may be a hydrogen-containing gas or a hydrogen-containing liquid. Examples of the hydrogen-containing gas include a hydrogen (H₂) gas, a hydrogen chloride (HCl) gas, a hydrogen bromide (HBr) gas, a hydrogen fluoride (HF) gas, and a hydrogen iodide (HI) gas. Examples of the hydrogen-containing liquid include hydrochloric acid (HCl), hydrobromic acid (HBr), and nitric acid (HNO₃). The substance containing chlorine may be a chlorine-containing gas. Examples of the chlorine-containing gas include Cl₂ and BCl₃. The substance containing bromine may be a bromine-containing gas. Examples of the bromine-containing gas include Br₂. The unexposed portion 18b may be removed by using at least one of a helium gas, a neon gas, an argon gas, a xenon gas, a nitrogen gas, a hydrocarbon gas, or a methanol (CH₃OH) gas. The unexposed portion 18b may be removed by plasma (asking) generated from a gas containing at least one of hydrogen, chlorine, or bromine. Alternatively, the unexposed portion 18b may be removed by using a gas containing at least one of hydrogen, chlorine, or bromine without using plasma. When the hydrogen bromide gas is used, the unexposed portions 18b can be removed without using plasma.

In Step ST2, as illustrated in FIGS. 3A and 3B, a filling portion FL1 (first filling portion) is formed in the opening OP1. The filling portion FL1 contains a second material different from the first material. The second material may be tin-free. The second material may contain at least one of carbon, silicon, or metal, Examples of the second material containing carbon include spin-on carbon (SOC) and the like. The metal may be metal other than tin. Examples of the metal include aluminum (Al), tungsten (W), titanium (Ti), hafnium (Hf), zirconium (Zr), and the like. The second material may contain a silicon-containing substance such as silicon oxide. Examples of the silicon-containing substance include spin-on-glass (SOG) and the like. When the first material contains tin, the second material may contain tin oxide. The oxygen concentration of the second material may be higher than the oxygen concentration of the first material. The first material may be oxygen-free. Step ST2 may be performed as follows.

First, as illustrated in FIG. 3A, a filling film FL1a with which the opening OP1 is filled is formed on the substrate W. The filling FL1a may be formed to cover the pattern PT1. The filling film FL1a may be formed by a wet process or a dry process.

Examples of the wet process include coating. For example, the liquid second material is applied onto the substrate W by using a spin coater. Then, the liquid second material is solidified by exposure or baking. As a result, the filling film FL1a can be formed.

Examples of the dry process include CVD. When the filling film FL1a contains silicon, for example, the filling film FL1a may be formed by CVD using a silicon-containing gas. Examples of the silicon-containing gas include a SiCl₄ gas, a Si₂Cl₆ gas, and a SiBr₄ gas. The silicon-containing gas is vaporized under conditions of a high temperature or low pressure and liquefied under conditions of a low temperature or high pressure. Thus, the liquid second material can be formed on the substrate W by adjusting at least one of the temperature or the pressure. Then, the liquid second material is solidified by oxidation or chlorine desorption. As a result, the filling film FL1a can be formed.

Then, as illustrated in FIG. 3B, the upper portion of the filling film FL1a is removed by, for example, etching or CMP, if necessary. Thus, the filling portion FL1 is formed from the filling film FL1a. When the filling film FL1a is, for example, a carbon-containing film, the filling film FL1a may be etched with, for example, a gas mixture of a nitrogen gas and a hydrogen gas, or an oxygen-containing gas. Examples of the oxygen-containing gas include an oxygen gas. When the filling film FL1a is, for example, a silicon-containing film, the filling film FL1a may be etched with, for example, a fluorine-containing gas. The fluorine-containing gas may contain carbon. Examples of the fluorine-containing gas include fluorocarbon (CₓF_{y}) gases.

In Step ST3, as illustrated in FIG. 3C, by removing the pattern PT1, the filling portion FL1 remains as a pattern PT2 (second pattern) inverted with respect to the pattern PT1. Using a substance containing at least one of hydrogen, chlorine, or bromine, the pattern PT1 can be etched at a high selectivity with respect to the filling portion FL1. When the pattern PT1 is removed by using the hydrogen bromide gas, it is possible to remove the pattern PT1 without using plasma. Therefore, it is possible to increase the etching selectivity of the pattern PT1 with respect to the filling portion FL1.

Examples of the substance for removing the pattern PT1 are the same as the examples of the substance for removing the unexposed portion 18b in Step ST1. The pattern PT1 may be removed by using at least one of a hydrogen fluoride gas, a hydrogen chloride gas, a hydrogen bromide gas, a hydrogen iodide gas, a fluorine gas, a chlorine gas, a bromine gas, an iodine gas, a boron trichloride gas, a helium gas, a neon gas, an argon gas, a xenon gas, a nitrogen gas, a hydrocarbon gas, or a methanol (CH₃OH) gas. The pattern PT1 may be removed by plasma (ashing) generated from a gas containing at least one of hydrogen, chlorine, or bromine. Alternatively, the pattern PT1 may he removed by using a gas containing at least one of hydrogen, chlorine, or bromine without using plasma.

After Step ST3, the underlying film UR may be etched by using the pattern PT2 as a mask. Thus, a pattern corresponding to the pattern PT2 is formed from the underlying film UR. Then, the oxide film 12 may be etched by using the obtained pattern as a mask. As a result, a pattern is formed. from the oxide film 12. Then, the silicon-containing film 10 may be etched by using the pattern obtained from the oxide film 12 as a mask.

According to the method MT in the present embodiment, the pattern can be inverted from the pattern PT1 to the pattern PT2. Since a photoresist film containing tin is usually a negative resist film, it is difficult to reduce the width (critical dimension) of a pattern formed from a photoresist film containing tin. However, according to the method MT in the present embodiment, it is possible to for m the pattern PT2 having relatively small width by reducing the width of the opening OP1 of the pattern PT1. Therefore, it is possible to form a contact hole having relatively small width in the silicon-containing film 10 by etching using the pattern PT2 as the mask. Furthermore, in the method MT in the present embodiment, by using a substance containing at least one of hydrogen, chlorine, or bromine in Step ST3, it is possible to selectively remove the pattern PT1 containing tin while leaving the filling portion FL1. The materials containing tin have the special property of being more reactive with substances containing at least one of hydrogen, chlorine, or bromine than many other materials. Therefore, when the pattern. PT1 containing tin is used, the number of choices for the material of the filling portion FL1 is increased.

### Second Embodiment

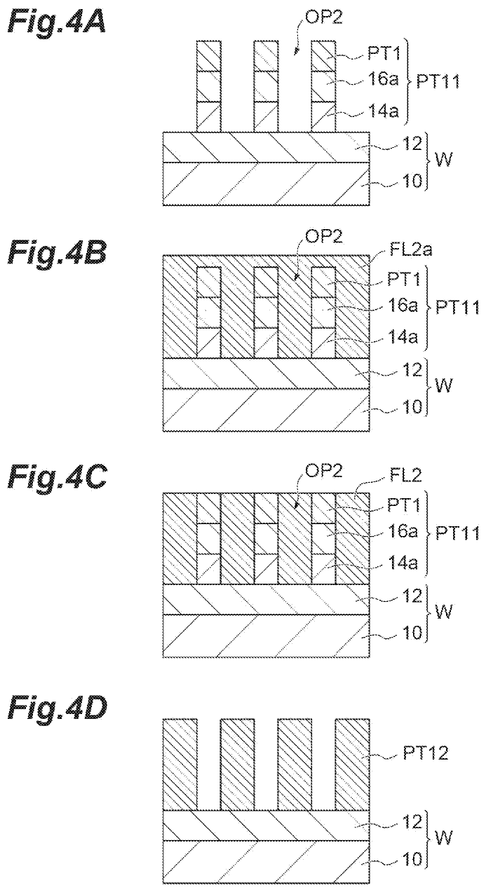

FIGS. 4A to 4D are cross-sectional views illustrating some steps of a pattern forming method according to a second embodiment. A method MT in the second embodiment will be described below with reference to FIGS. 1, 2A to 2C, and 4A to 4D.

In the present embodiment, in Step ST1, a pattern PT11 (first pattern) having an opening OP2 is formed on a substrate W, as illustrated in FIG. 4A. The pattern PT11 includes the same first material as the pattern PT1. Step ST1 may be performed as follows.

In Step ST1, first, a pattern PT1 (mask pattern) corresponding to the pattern PT11 is formed on an underlying film UR provided on the substrate W, as illustrated in FIGS. 2A to 2C. The pattern PT1 may be formed in the same manner as the manner in the first embodiment.

Then, as illustrated in FIG. 4A, the pattern PT11 is formed by etching the underlying film UR using the pattern PT1 as a mask. For example, a pattern 14a and a pattern 16a are formed from a first layer 14 and a second layer 16, respectively. The pattern PT11 may include the pattern PT1 the pattern 14a, and the pattern 16a.

In Step ST2, as illustrated in FIGS. 4B and 4C, a filling portion FL2 is formed in an opening OP2, The filling portion FL2 contains the same second material as the filling portion FL1. Step ST2 may be performed as follows.

First, as illustrated in FIG. 4B, a filling film FL2a with which the opening OP2 is filled is formed on the substrate W. The filling film FL2a may be formed to cover the pattern PT11. The filling film FL2a may be formed in the same manner as the manner of forming the filling film FL1a.

Then, as illustrated in FIG. 4C, the upper portion of the filling film FL2a may be removed if necessary. Thus, the filling portion FL2 is firmed from the filling film FL2a. The upper portion of the filling film FL2a may be removed in the same manner as the manner of removing the upper portion of the filling film FL1a.

In Step ST3, as illustrated in FIG. 4D, by removing the pattern PT11, the filling portion FL2 remains as a pattern PT12 (second pattern) inverted with respect to the pattern PT11. The pattern PT1 in the pattern PT11 may be removed by etching same as the etching in Step ST3 in the first embodiment. The pattern 14a and the pattern 16a in the pattern PT11 may be removed by etching same as the etching of the underlying film UR in the Step ST1 in the present embodiment.

According to the method MT in the present embodiment, it is possible to set the aspect ratio of the pattern PT12 to be larger than the aspect ratio of the pattern P12 in the first embodiment. Therefore, when the oxide film 12 is etched by using the pattern PT12 as a mask, a favorable etching selectivity can be obtained.

### Third Embodiment

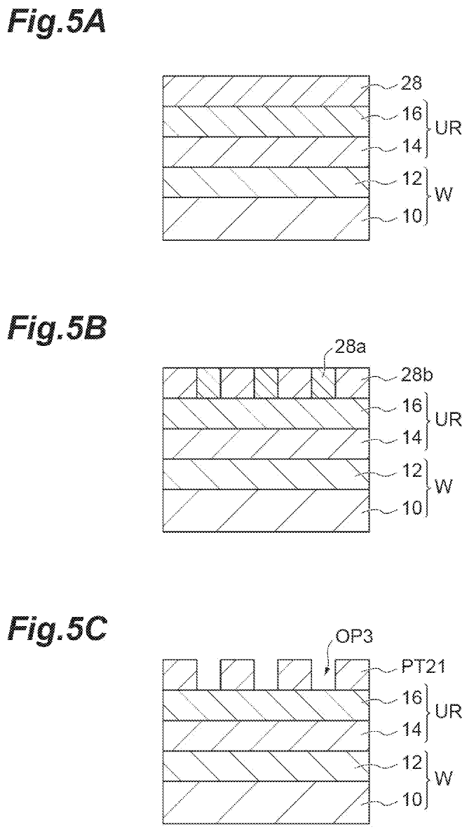

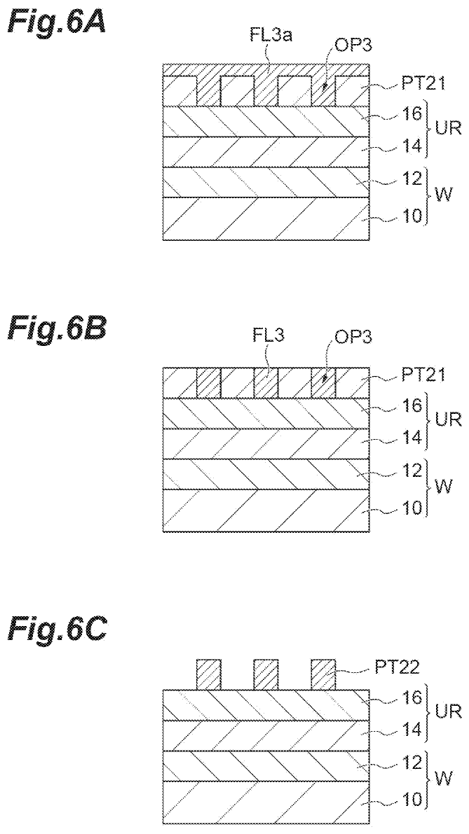

FIGS. 5A to 5C and FIGS. 6A to 6C are cross-sectional views illustrating some steps of the pattern forming method according to a third embodiment. A method MT in the third embodiment will be described below with reference to FIGS. 1 and 5A to 6C.

In Step ST1, a pattern PT21 (first pattern) having an opening OP3 is formed on a substrate W, as illustrated in FIGS. 5A to 5C. The pattern PT21 contains a first material. In the present embodiment, the first material may contain at least one of carbon, silicon, or metal. The first material may be tin-free. The first material in the present embodiment may be the same as the second material in the first embodiment. The opening OP3 is, for example, a hole. Step ST1 may be performed as follows.

First, a photoresist film 28 is formed on the substrate W as illustrated in FIG. 5A. The photoresist film 28 may be formed on the underlying film UR. The photoresist film 28 may contain at least one of carbon, silicon, or metal. The photoresist film 28 may be a positive resist film or a negative resist film. The photoresist film 28 may be formed by a wet process or a dry process. Examples of the wet process include coating. Examples of the dry process include CVD.

Then, as illustrated in FIG. 5B, the photoresist film 28 is exposed by using, for example, a photomask, An exposed portion 28a and an unexposed portion 28b are formed from the photoresist film 28 by the exposure.

Then, as illustrated in FIG. 5C, the opening OP3 is formed by removing the exposed portion 28a by development. As a result, the pattern PT21 is formed from the unexposed portion 28b. In this case, the photoresist film 28 is a positive resist film. When the photoresist film 28 is a negative resist film, the unexposed portion 28b is removed. Therefore, the pattern PT21 is formed from the exposed portion 28a.

In Step ST2, as illustrated in FIGS. 6A and 6B, a filling portion FL3 (first filling portion) is formed in the opening OP3. The filling portion FL3 contains a second material different from the first material. The second material contains tin. The second material may contain tin oxide. Examples of the second material include tin-containing organic materials and the like. The second material in the present embodiment may be the same as the first material in the first embodiment. Step ST2 may be performed as follows.

First, as illustrated in FIG. 6A, a filling film FL3a with which the opening OP3 is filled is formed on the substrate W. The filling film FL3a may be formed to cover the pattern PT21. The filling film FL3a may be formed by a wet process or a dry process. Examples of the wet process include coating. Examples of the dry process include CVD. The filling film FL3a may be formed by CVD using a tin-containing gas. Examples of the tin-containing gas include an organotin compound gas, a SnCl₄ gas, a Sn(CH₃)₄ gas, and a SnH₄ gas. The tin-containing gas is vaporized under conditions of a high temperature or low pressure and liquefied under conditions of a low temperature or high pressure. Thus, by adjusting at least one of the temperature or the pressure, it is possible to fill the opening OP3 with the liquid second material. Then, the liquid second material is solidified by oxidation or chlorine desorption. As a result, the filling film FL3a can be finned.

Then, as illustrated in FIG. 6B, the upper portion of the filling film FL3a is removed by, for example, etching or CMP, if necessary. Thus, the filling portion FL3 is formed from the filling film FL3a. The filling film FL3a may be removed by plasma (ashing) generated from a gas containing at least one of hydrogen, chlorine, or bromine. Alternatively, the filling film FL3a may be removed by using a gas containing at least one of hydrogen, chlorine, or bromine without using plasma.

In Step ST3, as illustrated in FIG. 6C, by removing the pattern PT21, the filling portion FL3 remains as a pattern PT22 (second pattern) inverted with respect to the pattern PT21. Using a substance that does not contain hydrogen, chlorine, and bromine, the pattern PT21 can be etched at a high selectivity with respect to the filling portion FL3.

When the pattern PT21 contains, for example, carbon, examples of a substance that does not contain hydrogen, chlorine, and bromine include an oxygen-containing gas, a fluorine-containing gas, and a nitrogen-containing gas. Examples of the oxygen-containing gas include an oxygen gas, a carbonyl sulfide (COS) gas, and a sulfur oxide (SO₂) gas. Examples of the fluorine-containing gas include a fluorocarbon (CₓF_{y}) gas, a hydrofluorocarbon (CₓH_{y}F_{z}) gas, and a nitrogen trifluoride (NF₃) gas. Examples of the nitrogen-containing gas include a nitrogen gas.

When the pattern PT21 contains silicon, for example, examples of the substance that does not contain hydrogen, chlorine, and bromine include a fluorine-containing gas. The fluorine-containing gas may contain carbon or nitrogen. Examples of the fluorine-containing gas include a fluorocarbon (CₓF_{y}) gas, a hydrofluorocarbon (CₓH_{y}F_{z}) gas, and a NF₃ gas.

When the pattern PT21 contains a metal other than tin, for example, examples of the substance that does not contain hydrogen, chlorine, and bromine include a fluorine-containing gas. Examples of the fluorine-containing gas include a hydrogen fluoride (HF) gas, a fluorocarbon (CₓF_{y}) gas, a NF₃ gas, and a SF₆ gas. The pattern PT21. may be removed as follows. First, the surface of the pattern PT21 is fluorinated by using a fluorine-containing gas. Then, the surface of the fluorinated pattern PT21 is exposed to a metal-containing precursor containing a metal complex. Examples of the metal-containing precursor include tin(II) acetylacetonate (Sn(acac)₂). Another highly volatile metal complex is produced by ligand exchange between a metal fluoride and a metal complex. As a result, the pattern PT21 is etched.

According to the method MT in the present embodiment, the pattern can be inverted from the pattern PT21 to the pattern PT22. Since a photoresist film containing tin is usually a negative resist film, it is difficult to reduce the width of a pattern formed from a photoresist film containing tin. However, according to the method MT in the present embodiment, it is possible to form the pattern PT22 having relatively small width by reducing the width of the opening OP3 of the pattern PT21. Therefore, it is possible to form a contact hole having relatively small width in the silicon-containing film 10 by etching using the pattern PT22 as the mask. Furthermore, in the method MT in the present embodiment, by using a substance that does not contain hydrogen, chlorine, and bromine in Step ST3, it is possible to selectively remove the pattern PT21 while leaving the filling portion FL3 containing tin. The materials containing tin have the special property of being less reactive with substances that do not contain hydrogen, chlorine, and bromine than many other materials. Therefore, when the filling portion FL3 containing tin is used, the number of choices for the material of the pattern PT21 is increased.

### Fourth Embodiment

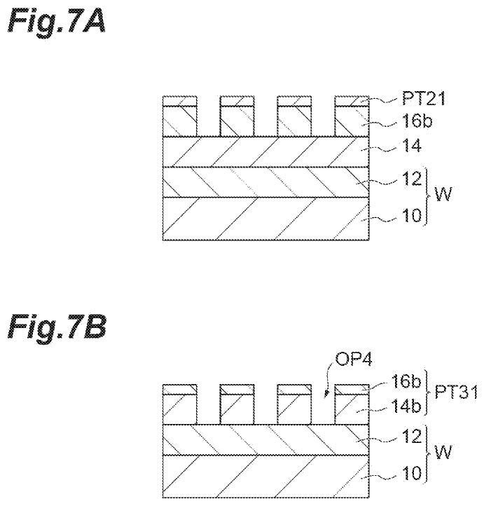

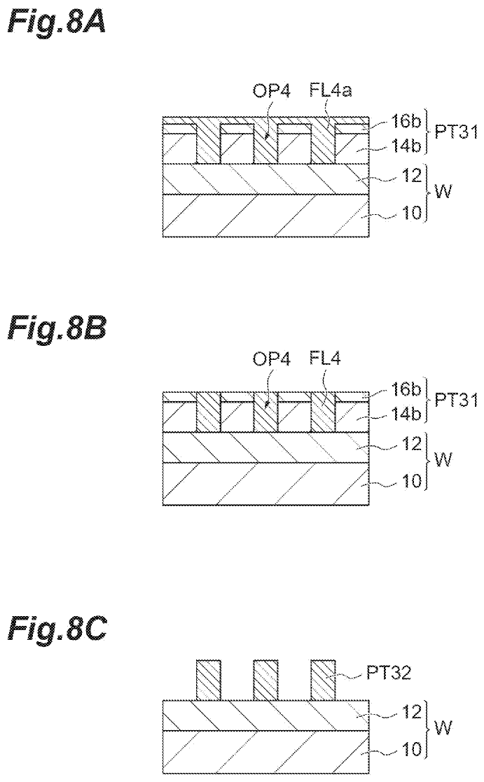

FIGS. 7A and 7B and FIGS. 8A to SC are cross-sectional views illustrating some steps of the pattern forming method according to a fourth embodiment. A method MT in the fourth embodiment will be described below with reference to FIGS. 1, 5A to 5C, and 7A to 8C. In the present embodiment, in Step ST1, a pattern PT31 (first pattern) having an opening OP4 is formed on a substrate W, as illustrated in FIGS. 7A and 7B. The pattern PT31 contains a first material. In the present embodiment, the first material may contain at least one of carbon, silicon, or metal. The first material may be tin-free. Step ST1 may be performed as follows.

in Step ST1, first, a pattern PT21 (mask pattern) corresponding to the pattern PT31 is formed on an underlying film UR provided on the substrate W, as illustrated in FIGS. 5A to 5C. The pattern PT21 may be formed in the same manner as the manner in the third embodiment.

Then, as illustrated in FIGS. 7A and 7B, the pattern PT31 is formed by etching the underlying film UR using the pattern PT21 as a mask. For example, a pattern 14b and a pattern 16b are formed from a first layer 14 and a second layer 16, respectively. The pattern PT21 may be removed when the underlying film UR is etched. The pattern PT31 may include the pattern 14b and the pattern 16b.

in Step ST2, as illustrated in FIGS. 8A and 8B, a filling portion FL4 is formed in an opening OP4. The filling portion FL4 contains the same second material as the filling portion FL3. Step ST2 may be performed as follows.

First, as illustrated in FIG. 8A, a filling film FL4a with which the opening OP4 is filled is formed on the substrate W. The filling film FL4a may be formed to cover the pattern PT31. The filling film FL4a may be formed in the same manner as the manner of forming the filling film FL3a.

Then, as illustrated in FIG. 8B, the upper portion of the filling film FL4a may be removed if necessary. Thus, the filling portion FL4 is formed from the filling film FL4a. The upper portion of the filling film FL444a may be removed in the same manner as the manner of removing the upper portion of the filling film FL3a.

In Step ST3, as illustrated in FIG. 8C, by removing the pattern PT31, the filling portion FL4 remains as a pattern PT32 (second pattern) inverted with respect to the pattern PT31. The pattern PT31 may be removed by etching same as the etching of the underlying film UR in Step ST1.

According to the method MT in the present embodiment, it is possible to set the aspect ratio of the pattern PT32 to be larger than the aspect ratio of the pattern PT22 in the third embodiment. Therefore, when the oxide film 12 is etched by using the pattern PT32 as a mask, a favorable etching selectivity can be obtained.

### Fifth Embodiment

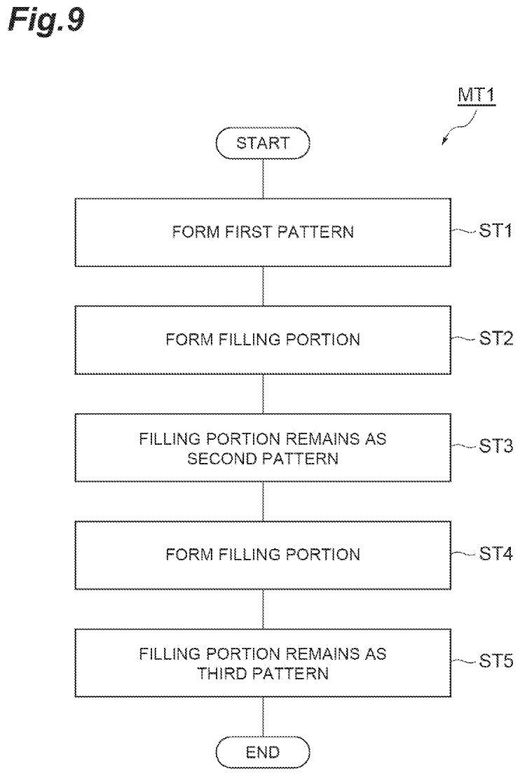

FIG. 9 is a flow diagram illustrating a pattern forming method according to one exemplary embodiment. A method illustrated in FIG. 9 (referred to as a “method MT1” below) further includes Steps ST4 and ST5 in addition to Steps ST1, ST2, and ST3. Steps ST4 and ST5 may be performed after Step ST3 in each of the first to fourth embodiments. Step ST5 may be performed after Step ST4. The method MT1 will be described below.

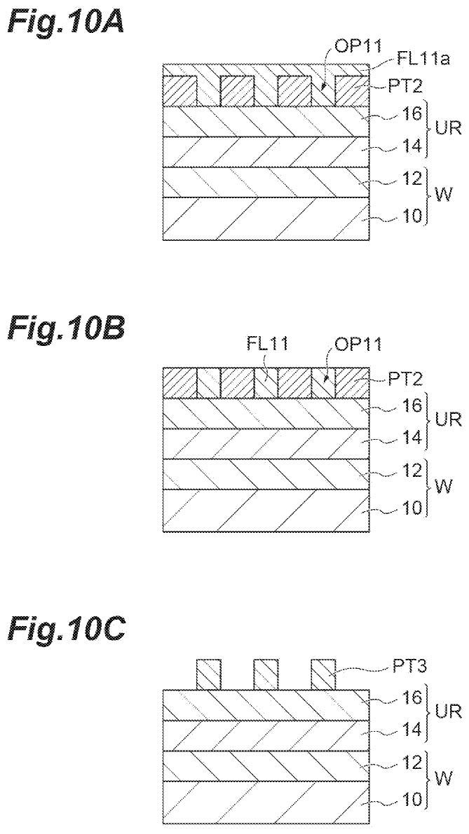

FIGS. 10A to 10C are cross-sectional views illustrating some steps of a pattern forming method according to a fifth embodiment. In the present embodiment, Step ST4 and Step ST5 may be performed after Step ST3 illustrated in FIG. 3C.

In Step ST4, as illustrated in FIGS. 10A and 10B, a filling portion FL11 (second filling portion) is formed in the opening OP11 of a pattern PT2. The filling portion FL11 contains a third material different from the first material and the second material. When first and second materials are the same as the first and second materials in the first embodiment, respectively, examples of a third material include carbon, silicon, and metals (except for tin).

Step ST4 may be performed in the same manner as Step ST2. First, as illustrated in FIG. 10A, a filling film FL11a with which the opening OP11 is filled is formed on the substrate W. The filling film FL11a may be formed to cover the pattern PT2. Then, as illustrated in FIG. 10B, the upper portion of the filling film FL11a is removed by, for example, etching or CMP, if necessary. Thus, the filling portion FL11 is formed from the filling film FL11a.

In Step ST5, as illustrated in FIG. 10C, by removing the pattern PT2, the filling portion FL11 remains as a pattern PT3 (third pattern) corresponding to the pattern PT1. Step ST5 may be performed in the same manner as Step ST3.

When the pattern PT2 contains carbon, and the filling portion FL11 contains metal other than tin or silicon, the pattern PT2 may be removed by an oxygen-containing gas or a nitrogen-containing gas. Examples of the oxygen-containing gas include an oxygen gas, a carbonyl sulfide (COS) gas, and a sulfur oxide (SO₂) gas. Examples of the nitrogen-containing gas include a nitrogen gas.

When the pattern PT2 contains silicon, and the filling portion FL11 contains carbon, the pattern PT2 may be removed by a halogen-containing gas. Examples of the halogen-containing gas include a fluorocarbon (CₓF_{y}) gas, hydrofluorocarbon (CₓF_{y}F_{z}) gas, a NF₃ gas, a hydrogen fluoride gas, a hydrogen chloride gas, and a hydrogen bromide gas.

When the pattern PT2 contains silicon, and the filling portion FL11 contains metal other than tin, the pattern PT2 may be removed by a fluorine-containing gas. Examples of the fluorine-containing gas include a fluorocarbon (CₓF_{y}) gas, a hydrofluorocarbon (CₓH_{y}F_{z}) gas, and a NF₃ gas.

When the pattern PT2 contains metal other than tin, and the filling portion FL11 contains carbon or silicon, the pattern PT2 may be removed by a hydrogen-containing gas or a halogen-containing gas. Examples of the hydrogen-containing gas include a hydrogen fluoride gas, a hydrogen chloride gas, a hydrogen bromide gas, and a hydrogen gas. Examples of the halogen-containing gas includes a chlorine gas and a bromine gas.

According to the method. MT1 in the present embodiment, it is possible to form the pattern PT3 that contains a material different from the material of the pattern PT1 and that has the same shape as the pattern PT1.

### Sixth Embodiment

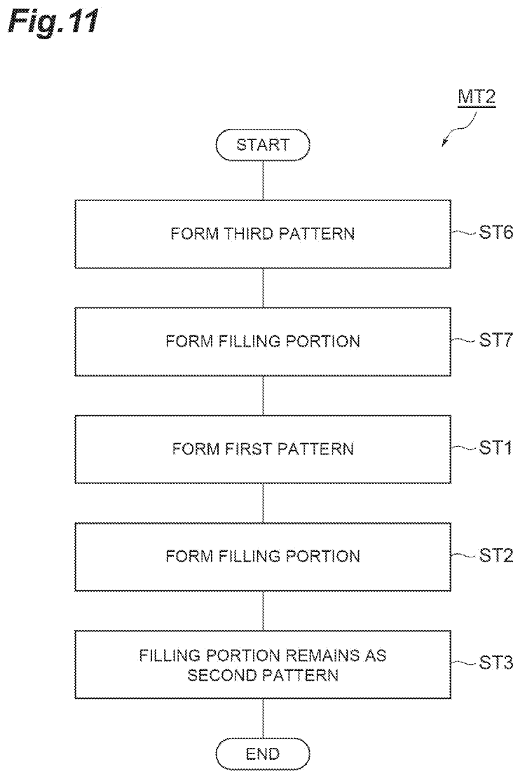

FIG. 11 is a flow diagram illustrating a pattern forming method according to one exemplary embodiment. A method illustrated in FIG. 11 (referred to as a “method MT2” below) further includes Steps ST6 and ST7 in addition to Steps ST1, ST2, and ST3. Steps ST6 and ST7 may be performed before Step ST1 in each of the first to fourth embodiments. Step ST6 may be performed before Step ST7. The method MT2 will be described below.

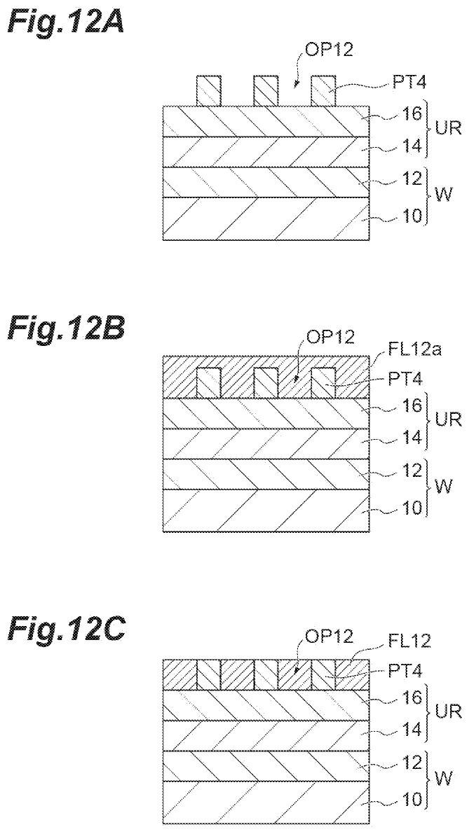

FIGS. 12A to 12C are cross-sectional views illustrating some steps of a pattern forming method according to a sixth embodiment. In the present embodiment, Step ST6 and Step ST7 may be performed before Step ST1 illustrated in FIG. 5C.

in Step ST6, a pattern PT4 (third pattern) having an opening OP12 is formed on a substrate W, as illustrated in FIG. 12A. The pattern PT4 contains a third material different from the first material and the second material. When the first and second materials are the same as the first and second materials in the third embodiment, respectively, examples of the third material include carbon, silicon, and metals (except for tin). Step ST6 may be performed in the same manner as Step ST1.

In Step ST7, a filling portion FL12 (second filling portion) is formed in the opening OP12 of the pattern PT4. The filling portion FL12 contains the first material.

Step ST7 may be performed in the same manner as Step ST2. First, as illustrated in FIG. 12B, a filling film FL12a with which the opening OP12 is filled is firmed on the substrate W. The filling film FL12a may be formed to cover the pattern PT4. Then, as illustrated in FIG. 12C, the upper portion of the filling film FL1.2a is removed by, for example, etching or CMP, if necessary. Thus, the filling portion FL12 is formed from the filling film FL12a.

After Step ST7, in Step ST1, by removing the pattern PT4, the filling portion FL12 remains as a pattern PT21 (first pattern) as illustrated in FIG. 5C.

When the pattern PT4 contains carbon, and the filling portion FL12 contains metal other than tin or silicon, the pattern PT4 may be removed by an oxygen-containing gas or a nitrogen-containing gas. Examples of the oxygen-containing gas include an oxygen gas, a carbonyl sulfide (COS) gas, and a sulfur oxide (SO₂) gas. Examples of the nitrogen-containing gas include a nitrogen gas.

When the pattern PT4 contains silicon, and the filling portion FL12 contains carbon, the pattern PT4 may be removed by a halogen-containing gas. Examples of the halogen-containing gas include a fluorocarbon (CₓF_{y}) gas, hydrofluorocarbon (CₓH_{y}F_{z}) gas, a NF₃ gas, a hydrogen fluoride gas, a hydrogen chloride gas, and a hydrogen bromide gas.

When the pattern PT4 contains silicon, and the filling portion FL12 contains metal other than tin, the pattern PT4 may be removed by a fluorine-containing gas. Examples of the fluorine-containing gas include a fluorocarbon (CₓF_{y}) gas, a hydrofluorocarbon (CₓH_{y}F_{z}) gas, and a NF₃ gas.

When the pattern PT4 contains metal other than tin, and the filling portion FL12 contains carbon or silicon, the pattern PT4 may be removed by a hydrogen-containing gas or a halogen-containing gas. Examples of the hydrogen-containing gas include a hydrogen fluoride gas, a hydrogen chloride gas, a hydrogen bromide gas, and a hydrogen gas. Examples of the halogen-containing gas includes a chlorine gas and a bromine gas.

According to the method MT2 in the present embodiment, it is possible to form the pattern PT22 that contains a material different from the material of the pattern PT4 and that has the same shape as the pattern PT4.

In each embodiment, the tin-containing pattern may be a Sn-containing film. The Sn-containing film may be formed by a dry process or a wet process. The Sn-containing film may be a Sn film or a SnO film. The Sn-containing film may be a photoresist film or a non-photoresist film. The pattern containing tin may be formed from any one of a CVD film, an ALD film, and a PVD film. The pattern containing tin may be formed by CND or ALD using, for example, t-butyltris(dimethylamino)tin as a precursor and using, for example, H₂O as an oxidizing agent. The CVD film, the ALD film, and the PVD film may be formed by plasma energy. The CVD film and the ALD film may be formed by thermal energy. The CVD film or the ALD film may be a photoresist film containing tin. The photoresist film may be a photoresist film for EUV exposure. When the unexposed portion of the photoresist film contains tin, and the exposed portion of the photoresist film contains tin oxide, the oxygen concentration in the exposed portion may be higher than the oxygen concentration in the unexposed portion. The unexposed portions may be oxygen-free.

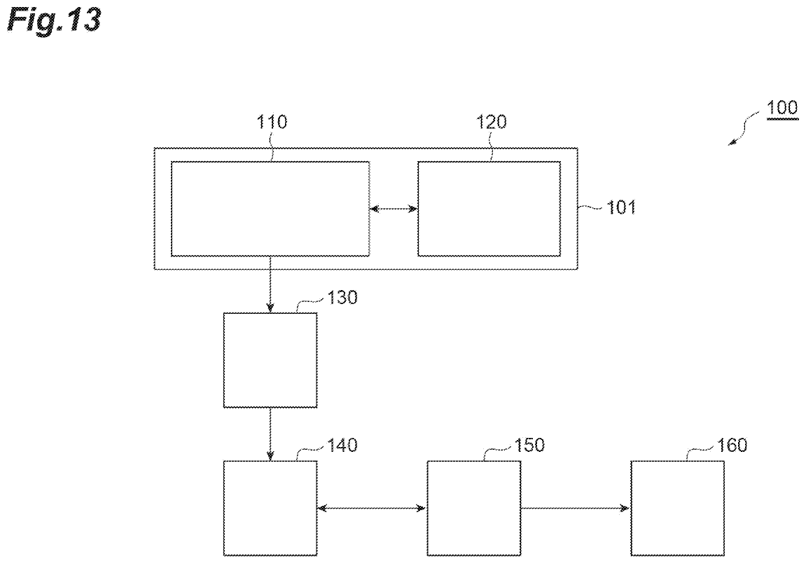

FIG. 13 is a diagram schematically illustrating an apparatus for performing a pattern forming method according to one exemplary embodiment. The method MT in each of the above embodiments may be performed by using an apparatus 100 illustrated in FIG. 13. The apparatus 100 may include a coating and developing device 110, an exposure device 120, a coating device 130, an etching device 140, an asher 150, and an etching device 160.

The coating and developing device 110 and the exposure device 120 may constitute a pattern forming device 101. A substrate W may be transported between the coating and developing device 110 and the exposure device 120, Step ST1 may be performed by using the pattern forming device 101. In Step ST1, the pattern PT1, the pattern PT11, the pattern PT21, or the pattern PT31 may be formed by using the pattern forming device 101. After Step ST1, the substrate W may be transported from the coating and developing device 110 to the coating device 130.

Step ST2 may be performed by using the coating device 130 and the etching device 140. The coating device 130 may be, for example, a spin coater or a slit coater. The apparatus 100 may include a CVD device instead of the coating device 130. The apparatus 100 may include a CMP device instead of the etching device 140. In Step ST2, the substrate W may be transported from the coating device 130 to the etching device 140. In Step ST2, the filling portion FL1, the filling portion FL2, the filling portion FL3, and the filling portion FL4 may be formed. After Step ST2, the substrate W may be transported from the etching device 140 to the asher 150.

Step ST3 may be performed by using the asher 150. The apparatus 100 may include a cleaning device instead of the asher 150. In Step ST3, the pattern PT1, the pattern PT11, the pattern PT21, or the pattern PT31 may be removed by using the asher 150. As a result, the pattern PT2, the pattern PT12, the pattern PT22, or the pattern PT32 may be formed. After Step ST3, the substrate W may be transported from the asher 150 to the etching device 160. The etching device 160 may be used for etching the oxide film 12 of the substrate W.

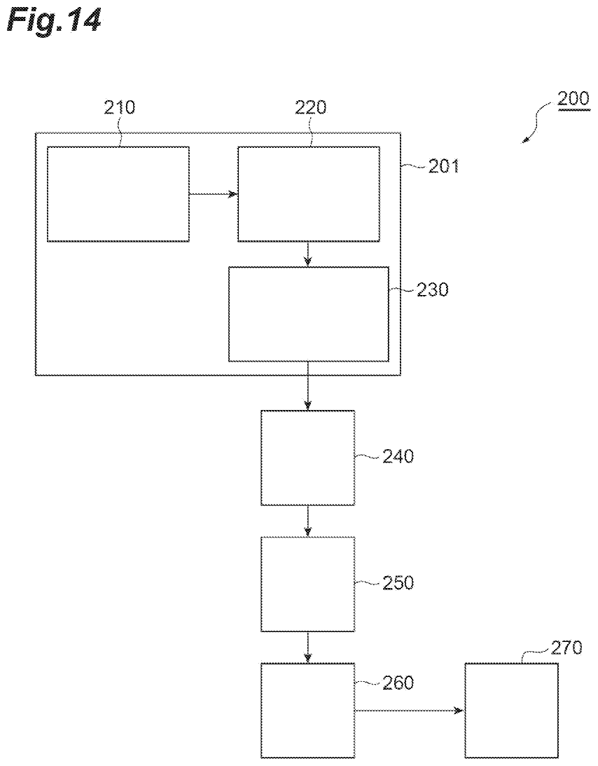

FIG. 14 is a diagram schematically illustrating an apparatus for performing a pattern forming method according to another exemplary embodiment. The method MT in each of the above embodiments may be performed by using an apparatus 200 illustrated in FIG. 14. By using the apparatus 200, it is possible to perform the method MT in each of the embodiments only by a dry process. The apparatus 200 may include a CVD device 210, an exposure device 220, an etching device 230, a CND device 240, an etching device 250, an asher 260, and an etching device 270.

The CVD device 210, the exposure device 220, and the etching device 230 may constitute a pattern forming device 201, The substrate W may be transported from the CVD device 210 to the etching device 230 through the exposure device 220. Step ST1 may be performed. by using the pattern forming device 201. In Step ST1, the pattern PT1, the pattern PT11, the pattern PT21, or the pattern PT31 may be formed by using the pattern forming device 201. After Step ST1, the substrate W may be transported from the etching device 230 to the CVD device 240.

Step ST2 may be performed by using the CVD device 240 and the etching device 250. In Step ST2, the substrate W may be transported from the CVD device 240 to the etching device 250. in Step ST2, the filling portion FL1, the filling portion FL2, the filling portion FL3, and the filling portion FL4 may be formed, After Step ST2, the substrate W may be transported from the etching device 250 to the asher 260.

Step ST3 may be performed by using the asher 260. After Step ST3, the substrate W may be transported from the asher 260 to the etching device 270. The etching device 270 may be used for etching the oxide film 12 of the substrate W

Although the various exemplary embodiments have been described above, various additions, omissions, substitutions, and changes may be made without being limited to the exemplary embodiments described above. Other embodiments can be formed by combining elements in different embodiments.

From the above description, it will be understood that various embodiments of the present disclosure have been described for purposes of explanation in the present specification, and that various changes may be made without departing from the scope and spirit of the present disclosure. Accordingly, the various embodiments disclosed in the present specification are not intended to limit, and the true scope and spirit are indicated by the appended claims.

What is claimed is:

1. A method for forming a pattern, the method comprising:
(a) forming, on a substrate, a first pattern having an opening and containing a first material;
(b) forming a filling portion in the opening, the filling portion containing a second material different from the first material; and
(c) removing the first pattern so that the filling portion remains as a second pattern inverted with respect to the first pattern, wherein
at least one of the first material or the second material contains tin.

2. The method according to claim 1, wherein
the first material contains tin.

3. The method according to claim 2, wherein
the first material contains tin oxide.

4. The method according to claim 2, wherein
the second material contains at least one of carbon, silicon, or metal.

5. The method according to claim 4, wherein
in (c), the first pattern is removed by using a hydrogen bromide gas.

6. The method according to claim 1, wherein
the second material contains tin.

7. The method according to claim 6, wherein
the second material contains tin oxide.

8. The method according to claim 6, wherein
the first material contains at least one of carbon, silicon, or metal.

9. The method according to claim 1, wherein
the first material contains tin,
the second material contains at least one of carbon, silicon, or metal, and
in (c), the first pattern is removed by using at least one of a hydrogen fluoride gas, a hydrogen chloride gas, a hydrogen bromide gas, a hydrogen iodide gas, a fluorine gas, a &twine gas, a bromine gas, an iodine gas, a boron trichloride gas, a helium gas, a neon gas, an argon gas, a xenon gas, a nitrogen gas, a hydrocarbon gas, or a methanol gas.

10. The method according to claim 9, wherein
the first material contains tin oxide, and
the second material contains at least one of carbon or silicon.

11. The method according to claim 10, wherein
in (c), the first pattern is removed by using at least one of the hydrogen bromide gas or the hydrocarbon gas.

12. The method according to claim1, wherein
the first material contains carbon,
the second material contains tin, and
in (c), the first pattern is removed by using at least one of an oxygen-containing gas, a fluorine-containing gas, or a nitrogen-containing gas.

13. The method according to claim 1, wherein
the first material contains silicon,
the second material contains tin, and
in (c), the first pattern is removed by using a fluorine-containing gas.

14. The method according to claim 1, wherein
the first material contains tin,
the second material contains tin oxide,
an oxygen concentration of the second material is higher than an oxygen concentration of the first material, and
in (c), the first pattern is removed by using at least one of a hydrogen fluoride gas, a hydrogen chloride gas, a hydrogen bromide gas, a hydrogen iodide gas, a fluorine gas, a chlorine gas, a bromine gas, an iodine gas, a boron trichloride gas, a helium gas, a neon gas, an argon gas, a xenon gas, a nitrogen gas, a hydrocarbon gas, or a methanol gas.

15. The method according to claim 9, wherein
an either one pattern containing tin of the first pattern and the second pattern is formed from a CVD film or an ALD film.

16. The method according to claim 15, wherein
the CVD film or the ALD film is a tin-containing photoresist film.

17. The method according to claim 16, wherein
the photoresist film is a photoresist film for EUV exposure.

18. The method according to claim 16, wherein
an unexposed portion of the photoresist film contains tin,
an exposed portion of the photoresist film contains tin oxide, and
an oxygen concentration in the exposed portion is higher than an oxygen concentration in the unexposed portion.

19. The method according to claim 1, wherein
(a) comprises:
(a1) forming a mask pattern corresponding to the first pattern, on an underlying film provided on the substrate, and
(a2) forming the first pattern by etching the underlying film with the mask pattern.

20. The method according to claim 19, wherein
the underlying film includes at least one of a silicon-containing film or a carbon-containing film.

21. The method according to claim 1, wherein
the filling portion is a first filling portion, and
the method further comprises:
(d) forming a second filling portion containing a third material different from the first material and the second material, in an opening of the second pattern; and
(e) removing the second pattern so that the second filling portion remains as a third pattern corresponding to the first pattern.

22. The method according to claim 1, wherein
the filling portion is a first filling portion, and
the method further comprises, before (a);
(f) forming, on the substrate, a third pattern having an opening and containing a third material, the third material being different from the first material and the second material, and
(g) forming a second filling portion containing the first material in the opening of the third pattern, and wherein
in (a), the third pattern is removed so that the second filling portion remains as the first pattern.

23. An apparatus for forming a pattern, the apparatus comprising:
a device for forming, on a substrate, a first pattern having an opening and containing a first material;
a device for forming a filling portion in the opening, the filling portion containing a second material different from the first material; and
a device for removing the first pattern so that the filling portion remains as a second pattern inverted with respect to the first pattern, wherein
at least one of the first material or the second material contains tin.
